(19) United States
(12) Patent Application Publication
(10) Pub. No.: US 2026/0254440 A1
(43) Pub. Date: Aug. 27, 2026

(54) APPARATUS AND TECHNIQUES FOR JAMMER SIGNAL FILTERING

(71) Applicant: QUALCOMM Incorporated, San Diego, CA (US)

(72) Inventors: Alexander SO, San Jose, CA (US); Ahmadreza DANESH, Irvine, CA (US); Zhijie XIONG, San Jose, CA (US)

(21) Appl. No.: 19/059,943

(22) Filed: Feb. 21, 2025

(51) Int. Cl. H03H 11/04; H03F 3/24

(52) U.S. Cl. CPC H03H 11/04; H03F 3/245; H03F 2200/294

(57) ABSTRACT

Certain aspects of the present disclosure are directed towards techniques and apparatus for signal filtering. An example filter circuit generally includes: a first transistor including a first terminal coupled to a node; a second transistor including a first terminal coupled to the node; a first capacitive circuit coupled between a second terminal of the first transistor and a first clock node, the second terminal of the first transistor being further coupled to a gate of the second transistor; and a second capacitive circuit coupled between a second terminal of the second transistor and a second clock node, the second terminal of the second transistor being further coupled to a gate of the first transistor.

### BACKGROUND

### Field of the Disclosure

Certain aspects of the present disclosure generally relate to electronic components and, more particularly, to a filter circuit.

### Description of Related Art

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems (e.g., a Long Term Evolution (LTE) system or a New Radio (NR) system). Wireless devices may include transmitters for processing signals for transmission via antennas. A receiver may include one or more low-noise amplifiers to amplify a signal for processing. In some cases, one or more filters may be used to reject (e.g., attenuate) jammer signals within a transmitter or receiver.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide the advantages described herein.

Certain aspects of the present disclosure are directed towards a filter circuit. The filter circuit generally includes: a first transistor including a first terminal coupled to a node; a second transistor including a first terminal coupled to the node; a first capacitive circuit coupled between a second terminal of the first transistor and a first clock node, the second terminal of the first transistor being further coupled to a gate of the second transistor; and a second capacitive circuit coupled between a second terminal of the second transistor and a second clock node, the second terminal of the second transistor being further coupled to a gate of the first transistor.

Certain aspects of the present disclosure are directed towards a method for signal filtering. The method generally includes: sampling, via a first transistor, a voltage at a node and on a first capacitive circuit during a first phase of a clock signal; generating, via the first capacitive circuit, a first level-shifted voltage at a gate of a second transistor during a second phase of the clock signal, the second phase being after the first phase; and sampling, via the second transistor, the voltage at the node and on a second capacitive circuit during the second phase based on the first level-shifted voltage.

Certain aspects of the present disclosure are directed towards an amplifier. The amplifier generally includes: an input transistor with a gate coupled to an input voltage node; a cascode transistor with a source coupled to a drain of the input transistor; and a first filter coupled between a source of the cascode transistor and a gate of the cascode transistor.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a diagram of an example wireless communications network, in which certain aspects of the present disclosure may be practiced.

FIG. 2 is a block diagram of an example access point (AP) and example user terminals, in which certain aspects of the present disclosure may be practiced.

FIG. 3 is a block diagram of an example transceiver front end, in which certain aspects of the present disclosure may be practiced.

FIGS. 4A-4D illustrate an example low-noise amplifier (LNA) implemented with notch filters for jammer rejection, in accordance with certain aspects of the present disclosure.

FIG. 5 illustrates an n-path filter.

FIG. 6 illustrates an n-path filter implemented with a cross-coupled switch structure, in accordance with certain aspects of the present disclosure.

FIG. 7 is a timing diagram illustrating level-shifted gate voltages and non-overlapping clock signals, in accordance with certain aspects of the present disclosure.

FIG. 8 illustrates an example LNA implemented with a notch filter having a cross-coupled switch structure, in accordance with certain aspects of the present disclosure.

FIG. 9 illustrates an example n-path filter implemented with a cross-coupled switch structure, in accordance with certain aspects of the present disclosure.

FIG. 10 is a flow diagram illustrating example operations for signal filtering, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards an n-path filter that may be implemented using a cross-coupled switch structure. The cross-coupled switch structure may be coupled to capacitive circuits that may be used to generate level-shifted voltages for driving transistors used to implement the switches of the n-path filter. In this manner, the driving strength of the transistors may be increased, reducing the on-resistance of the n-path filter and increasing the out-of-band jammer rejection of the n-path filter. In some cases, the actual or effective capacitances of the capacitive circuits may be adjusted to adjust a filtering bandwidth associated with the n-path filter. For example, the capacitive circuits may be implemented as capacitor banks with switches that may be controlled to adjust the effective capacitance, and hence the filtering bandwidth.

Certain aspects are directed towards an amplifier with an input transistor and a cascode transistor, where one or more filters may be coupled to a cascode node between the input transistor and the cascode transistor to filter out-of-band jammer signals. The one or more filters may include a notch filter coupled between a gate and a source of the cascode transistor, effectively shorting the gate and the source of the cascode transistor in the presence of a jammer signal such that the cascode transistor does not amplify the jammer signal. At the jammer signal frequency, the gate of the cascode device may also act as electric ground (e.g., reference potential node). Thus, the jammer signal may be directed to ground through the notch filter. In some cases, the one or more filters may include another filter between the cascode node and ground, as described in more detail herein. The one or more filters may be implemented as any suitable notch filter(s), such as an n-path filter using a cross-coupled switch structure as described.

The one or more notch filters may present high impedance (e.g., block) for signals having frequencies within the operating band of the amplifier, yet may present low impedance to jammer signals having frequencies that are outside the operating band, routing the jammer signals to ground. In this manner, the filters effectively implement a band-pass filter characteristic for the amplifier by filtering out signals outside the operating band.

The structure described herein provides filtering with improved performance while providing an adjustable bandwidth and center frequency tracking. The LNA structure may be implement with filters that can be disabled when jammer signals are not present, providing improved LNA performance in terms of noise and power consumption.

### Example Wireless Communications

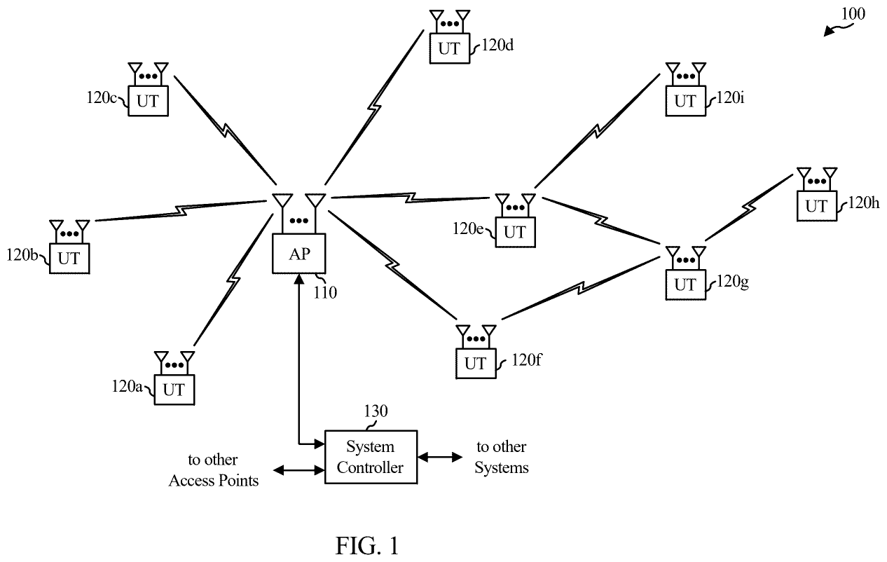

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), a next generation Node B (gNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported).

In some aspects, the user terminal 120 or access point 110 may include a filter implemented with a cross-coupled switch structure.

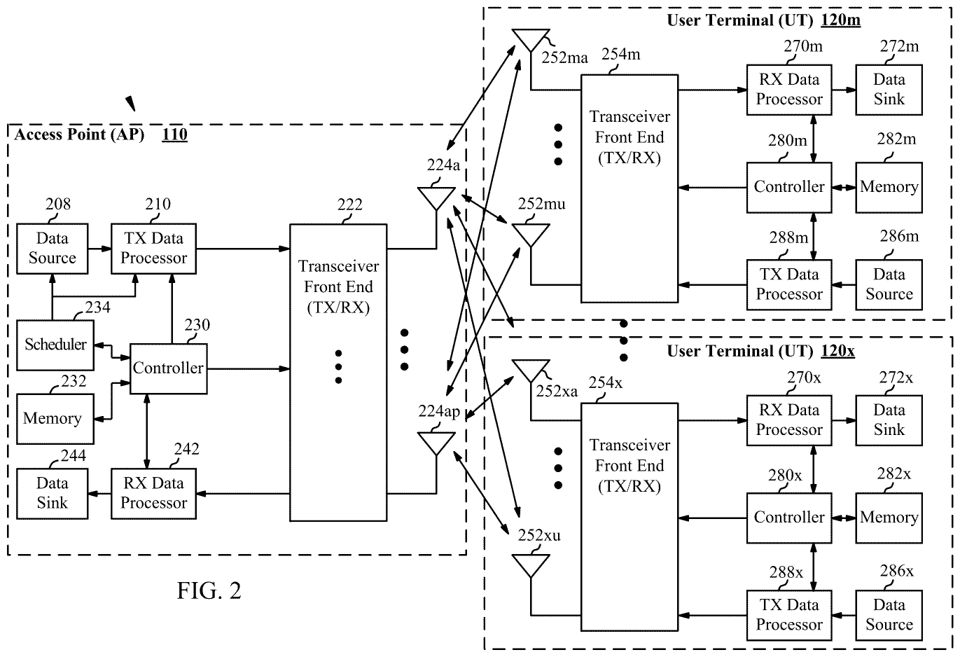

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering, beamforming, or some other spatial processing technique may be used at the access point and/or user terminal.

On the uplink, at each user terminal 120 selected for uplink transmission, a transmitter (TX) data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. A receiver (RX) data processor 242 processes (e.g., demodulates, deinterleaves, and decodes) the recovered uplink data symbol stream in accordance with the rate used for that stream to obtain decoded data. The decoded data for each user terminal may be provided to a data sink 244 (e.g., corresponding to data sink 272 of UT) for storage and/or a controller 230 for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one or more of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

In some aspects, the transceiver front end 254 or 222 may include a filter implemented with a cross-coupled switch structure.

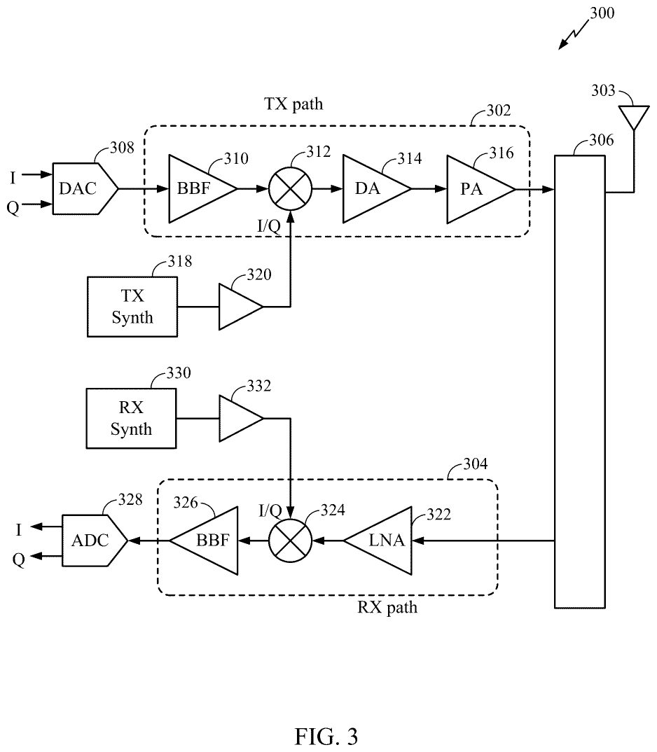

FIG. 3 is a block diagram of an example transceiver front end 300, such as transceiver front ends 222, 254 in FIG. 2, in which aspects of the present disclosure may be practiced. The transceiver front end 300 includes at least one transmit (TX) path 302 (also known as a transmit chain) for transmitting signals via one or more antennas and at least one receive (RX) path 304 (also known as a receive chain) for receiving signals via the one or more antennas. When the TX path 302 and the RX path 304 share an antenna 303, the paths may be connected with the antenna via an interface 306, which may include any of various suitable RF devices, such as a switch, a duplexer, a diplexer, a multiplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, the DA 314, and the PA 316 may be included in a radio frequency integrated circuit (RFIC). In some cases, the PA 316 may be external to the RFIC. In some cases, the DA 314 may include a pre-DA that may drive a DA, where the DA drives the PA 316.

The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency-conversion process produces the sum and difference frequencies of the LO frequency and the frequencies of the baseband signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303. While one mixer 312 is illustrated, several mixers may be used to upconvert the filtered baseband signals to one or more intermediate frequencies and to thereafter upconvert the intermediate frequency (IF) signals to a frequency for transmission.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (e.g., downconvert). The baseband signals output by the mixer 324 may be filtered by the BBF 326 before being converted by an analog-to-digital converter (ADC) 328 to digital I and/or Q signals for digital signal processing.

Certain transceivers may employ a variable-frequency oscillator (e.g., a voltage-controlled oscillator (VCO) or a digitally controlled oscillator (DCO)) to generate a stable, tunable LO signal with a particular tuning range. Thus, the transmit LO signal may be produced by a TX frequency synthesizer 318, which may be buffered or amplified by amplifier 320 before being mixed with the baseband signals in the mixer 312. Similarly, the receive LO signal may be produced by an RX frequency synthesizer 330, which may be buffered or amplified by amplifier 332 before being mixed with the RF signals in the mixer 324. For certain aspects, a single frequency synthesizer may be used for both the TX path 302 and the RX path 304.

In certain aspects, the transceiver front end 300 may include a filter implemented with a cross-coupled switch structure. The filter may be coupled to a cascode node of the LNA 322, in some cases.

While FIGS. 1-3 provide wireless communications as an example application in which certain aspects of the present disclosure may be implemented to facilitate understanding, certain aspects described herein may be used in any of various other suitable systems.

### Example Techniques for Signal Filtering

The coexistence of multi-protocol and multi-band transceivers is a continuous challenge. One common example in recent WiFi receiver (RX) front-end devices is the rejection of a 2.4 GHz signal for 5G WiFi. The WiFi receiver may perform simultaneous communications on a 2.4 GHz band and a 5 GHz band. As a result, the 2.4 GHz band signal may become a jammer signal, interfering with the 5 GHz band operations. The presence of jammer signals is an increasingly complex problem as next-generation devices use more bands and more protocols operating together. In particular, out-of-band jammers become a problem when jammers are integer multiples of the frequency of interest. Harmonic distortion from nonlinear amplification (such as in an LNA or buffer amplifiers) and mixing products may allow the out-of-band jammers to corrupt the signal at the frequency of interest.

In some cases, a resistor-inductor-capacitor (RLC) notch filter (e.g., in the RX path 304) may be used to reject jammer signals. The RLC notch filter may introduce losses and provide low filtering and bandwidth due to the finite quality factor (Q) of the RLC notch filter. In some cases, off-chip (e.g., external to a radio frequency integrated circuit (RFIC)) surface acoustic wave (SAW)/bulk acoustic wave (BAW) filters (e.g., in the interface 306) may be used to reject jammer signals, offering increased filter performance but adding cost, adding front-end power losses, and may not address on-chip jammer presence. SAW/BAW filters generally also do not provide the ability to tune the filtering bandwidth. Moreover, SAW/BAW filters may be unable to provide the ability to tune the center frequency of the filters. Thus, peripheral circuitry such as a multiplexer and other filters may be used to perform frequency selection.

Certain aspects of the present disclosure are directed towards a filtering circuit that may be implemented at a cascode node of a low-noise amplifier (LNA) for jammer rejection. The cascode node may be a low-impedance node of the LNA. Thus, the filter circuit may include a notch filter implemented between a gate and a source of a cascode transistor of the LNA, in effect shorting the gate and source of the cascode transistor at a jammer frequency to reduce any amplification of the jammer signal that the cascode transistor would otherwise provide. The filter circuit may be implemented as any suitable notch filter. In some cases, the filter circuit may be implemented as a notch filter with a cross-coupled switch structure, providing increased jammer rejection and the ability to tune the bandwidth of the notch filter.

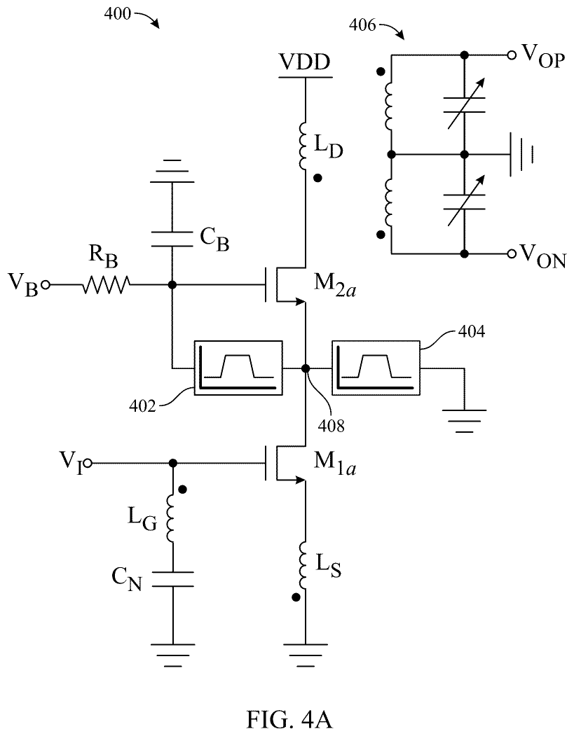

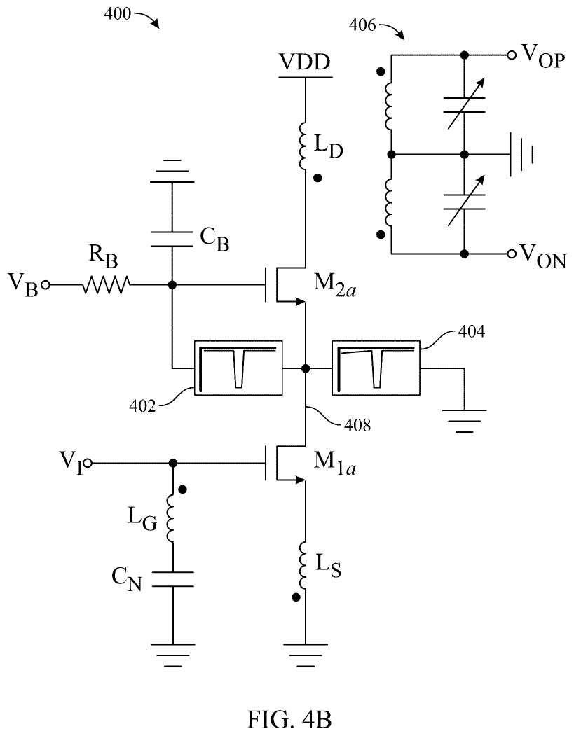

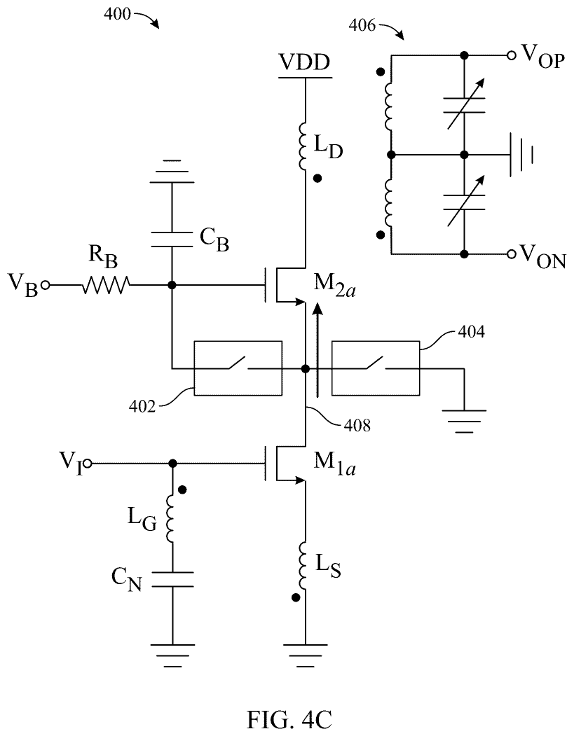

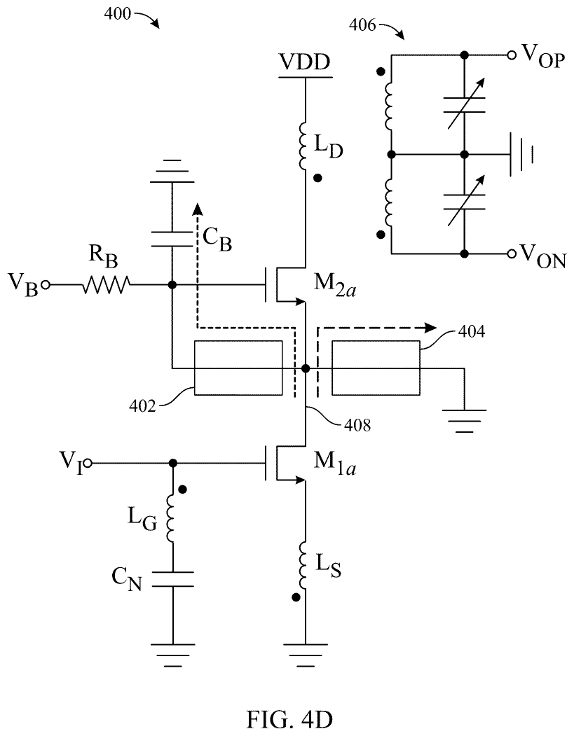

FIG. 4 illustrates an example LNA 400 implemented with notch filters for jammer rejection, in accordance with certain aspects of the present disclosure. As shown, the LNA 400 may include an input transistor M₁ₐ having a gate coupled to an input voltage (V_{I}) node. A matching network may be coupled to the gate and source of the input transistor M₁ₐ. The matching network may include an inductive element L_{G} and a capacitive element CN coupled in series between the gate of transistor M₁ₐ and a reference potential node (e.g., electric ground). The matching network may also include an inductive element L_{S} coupled between the source of transistor M₁ₐ and the reference potential node, where the inductors L_{S} and L_{G} are magnetically coupled to form a reactive feedback matching network. Although an example matching network is shown to facilitate understanding, any suitable matching network structure may be used.

The LNA 400 may also include a cascode transistor M₂ₐ coupled in cascode with the input transistor M₁. That is, the drain of transistor M₁ₐ may be coupled to a source of transistor M₂ at a cascode node 408. The gate of transistor M₂ₐ may be coupled to a bias voltage (V_{B}) node through a bias resistive element R_{B}. A capacitive element C_{B} may be coupled between the gate of transistor M₂ₐ and the reference potential node (e.g., electric ground). The drain of transistor M₂ₐ may be coupled to a voltage rail VDD through an inductive element L_{D}. The inductive element L_{D} may be magnetically coupled to inductive elements of an output structure 406 (e.g., implementing a balanced-unbalanced (balun) device) to generate positive and negative output voltages V_{OP} and V_{ON}, as shown.

In some aspects of the present disclosure, one or more filters may be coupled to the cascode node 408. For example, a filter 404 may be coupled between the cascode node 408 and the reference potential node, and a filter 402 may be coupled between the cascode node 408 and the gate of transistor M₂. Each of the filters 402, 404 may be implemented using any suitable notch filter, providing high impedance to signals having particular frequencies within an operating band of the LNA 400 and low impedance to signals having frequencies outside the operating band. For example, each of the filters 402, 404 may be implemented as an RLC filter or an n-path filter. Each notch filter may include a notch frequency set to reject a jammer signal. For example, WiFi may be implemented with a 5 GHz transceiver and a 2.4 GHz transceiver, where the 2.4 GHz signal from the 2.4 GHz transceiver may be a jammer signal for the 5 GHz transceiver, as described herein. Thus, for the 5 GHz transceiver, each of the filters 402, 404 may be implemented to reject (filter out) any signal outside the 5 GHz bandwidth, including the 2.4 GHz jammer signal. For in-band signals (e.g., signals within the 5 GHz bandwidth), the LNA design may behave as a typical cascode amplifier (e.g., LNA amplifier), assuming the filters have low insertion loss.

In FIG. 4A, the filters 402, 404 are shown as blocks including plots of the impedance seen looking into each filter as a function of frequency. That is, as shown, each filters presents a high impedance to signals within a certain frequency band and low impedance to signals outside the frequency band. In FIG. 4B, the filters 402, 404 are shown as blocks including plots of the level of attenuation provided by each filter as a function of frequency. In effect, each of the filters creates a frequency dependent impedance to ground. Each of the filters 402, 404 may, in effect, act as a switch that can be in an opened state with respect to out-of-band signals as shown in FIG. 4C and in a closed state with respect to in-band signals as shown in FIG. 4D.

For out-of-band signals (e.g., jammer signal), the filter 404 may shunt the signal (e.g., alternating current (AC) signal from the drain of transistor M₁ₐ to the source of transistor M₂ₐ) to the reference potential node (e.g., ground) as shown in FIG. 4D. However, the impedance presented at the cascode node 408 may be approximately equal to the inverse of the transconductance of the transistor M₂ₐ. Thus, the cascode node 408 may be a low-impedance node. As a result, the filter 402 may be implemented between the source and the gate of transistor M₂ₐ. For the out-of-band signal, the filter 402 may short the gate and the source of the transistor M₂ₐ such that any change in the source voltage of transistor M₂ₐ results in the same change in the gate voltage of transistor M₂ₐ, effectively setting the gate-to-source voltage of transistor M₂ₐ to zero. Moreover, the capacitive element C_{B} may act as a short at the frequencies of jammer signals, effectively directing the jammer signals at node 408 to the reference potential node (e.g., ground) as shown in FIG. 4D. The LNA structure with the filter 402 and/or filter 404 provides increased jammer rejection as compared to a typical LNA.

In some aspects, the filters 402, 404 may be enabled or disabled (e.g., depending on the operating mode of a wireless device including the LNA or the expected presence of jammer signals). For example, as described in more detail herein, each of the filters 402, 404 may be implemented as an n-path filter. To disable an associated filter, the switches of the n-path filter may be opened (e.g., remain in an open state as opposed to being controlled via clock signals), as described in more detail herein. By turning off each filter in the absence of a jammer signal, the LNA performance may be increased (e.g., increased to match the LNA performance without filters 402, 404). That is, any loss or penalty in noise figure/sensitivity due to the filters may be avoided (or at least reduced) by disabling the filters.

With filters 402, 404 being coupled to the cascode node 408, the filters may be independent of (e.g., not impacted by) the input matching network of the LNA 400 and the output balun design (output structure 406). While any suitable notch filters may be used for filters 402, 404, the filters may be implemented as n-path filters in some aspects. As described in more detail herein, the n-path filter may be implemented with a cross-coupled switch structure, providing a filter with a tunable bandwidth, low insertion loss, and increased jammer rejection as compared to other filter types.

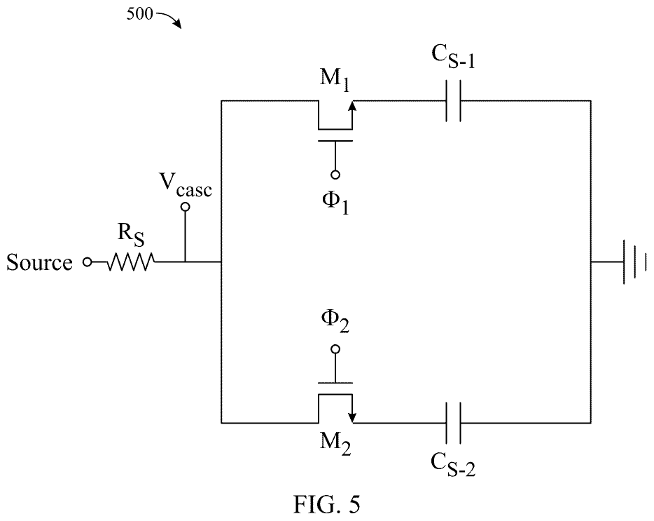

FIG. 5 illustrates an example n-path filter 500, in accordance with certain aspects of the present disclosure. The n-path filter 500 may be used to implement the filter 402 or filter 404. An n-path filter may include a series of switches (e.g., switches implemented using transistor M₁ and M₂) coupled between the cascode node 408 (e.g., having a voltage labeled “Vcasc”) of the filter and a respective sampling capacitive element (e.g., capacitive elements C_{S-1} and C_{S-2}). While the example n-path filters described herein are described as being coupled to a cascode node (e.g., Vcasc node), the n-path filters may be coupled to any suitable node of any circuit for filtering. As shown, resistive element R_{S} may be coupled between a source and the node 408. The resistive element R_{S} may represent the source impedance of a circuit, such as the LNA 400. For instance, the resistive element R_{S} may represent the impedance of the LNA at the cascode node 408, looking towards the drain of the input transistor M₁.

Non-overlapping clock signals (φ₁ and φ₂) may be used to drive the gates of respective transistors M₁ and M₂. The non-overlapping clock signals may have the same period but logic-high phases that are non-overlapping in time (e.g., occur at different times). Based on the non-overlapping sampling clock signals (φ₁ and φ₂), the Vcasc may be sampled on each of the capacitive elements C_{S-1} and C_{S-2} during the non-overlapping phases (e.g., Vcasc may be sampled on capacitive element C_{S-1} during a first phase and sampled on capacitive C_{S-2} during a second phase after the first phase). When the sampling frequency of the sampling clock signals is equal to the frequency of a signal at an input node of the filter, the filter blocks (e.g., presents high-impedance to) the signal, effectively implementing a notch filter. Otherwise, the filter may present a low impedance for the signal, allowing the signal to pass. The switches (transistors M₁ and M₂) of the n-path filter may provide a sampling and mixing operation that translates a baseband response to the switching frequency. Due to the mixing, when the input signal frequency matches the sampling frequency, the voltage at the cascode node 408 tracks the input voltage and is attenuated otherwise. Filter parameters such as the out-of-band (OOB) rejection, insertion loss, and corner frequency associated with the n-path filter may be calculated using the following equations:

$$OOB Rejection = \frac{{R}_{ON} + {R}_{S}}{{R}_{ON}}$$

$$Insertion Loss = \frac{{R}_{S}}{{R}_{S} + {R}_{OFF}}$$

$$Corner Frequency = \frac{1}{2 π RC}$$

where R_{ON} is the on-resistance of transistor M₁, which may be equal to the on-resistance of transistor M₂, ROFF is the off-resistance of transistor M₁ or transistor M₂, R is the resistance of R_{S} (e.g., assuming the on-resistances of the n-path filter transistors is much less than R_{S}), and C is the capacitance of capacitive element C_{S-1} which may be equal to the capacitance of capacitive element C_{S-2}. While example n-path filters are described herein with two sampling phases to facilitate understanding, any suitable number of sampling phases may be used, where using more phases reduces the filter's insertion loss.

The n-path filter 500 may have little to no bandwidth adjustability. In some implementations, to allow for adjustability of the filter bandwidth, the sampling capacitive elements may be implemented as capacitor banks. However, capacitor banks include switches that increase the total sampling path resistance of the filter, resulting in reduced OOB rejection. Adding more filters in parallel may improve OOB rejection at the expense of insertion loss. Certain aspects of the present disclosure are directed toward an n-path filter implemented with a cross-coupled switch structure, providing adjustability of the filter bandwidth while maintaining a high OOB rejection and low insertion loss

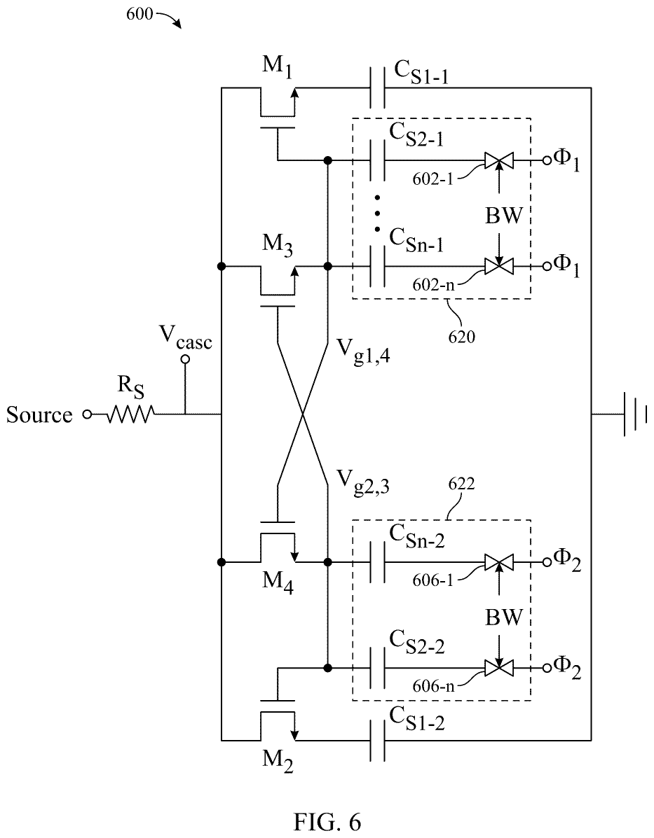

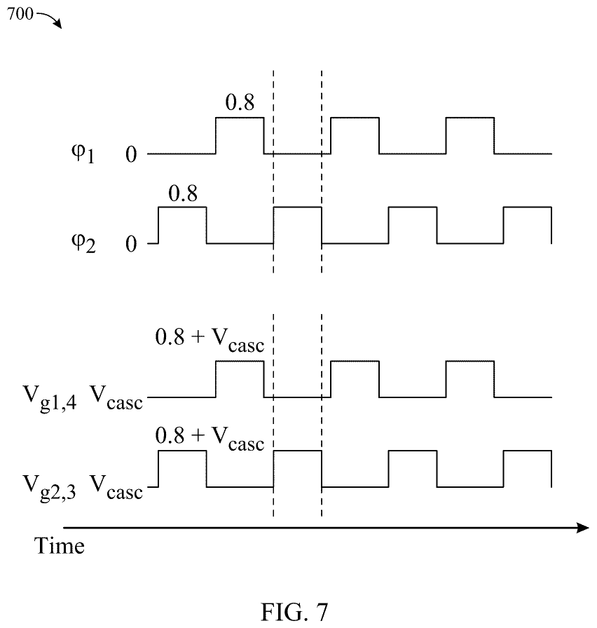

FIG. 6 illustrates an example n-path filter 600 implemented with a cross-coupled switch structure, in accordance with certain aspects of the present disclosure. As shown, the filter 600 includes transistors M₁, M₂ for sampling Vcasc on sampling capacitive elements C_{S1-1} and C_{S1-2}. In addition, the filter 600 may also include a transistor M₃ for sampling Vcasc on a capacitor bank 620 implemented via capacitive elements C_{S2-1} to C_{Sn-1}, and include a transistor M₄ for sampling Vcasc on a capacitor bank 622 implemented via capacitive elements C_{S2-2} to C_{Sn-2}, where n is any positive integer. Transistors M₃, M₄ may form a cross-coupled switch structure. That is, the gate of transistor M₄ may be coupled to the source of transistor M₃, and the gate of transistor M₃ may be coupled to the source of transistor M₄. The capacitor banks 620, 622 are coupled between respective clock nodes receiving non-overlapping clock signals φ₁ and φ₂. During a first phase, transistors M₁, M₄ are turned on, and during a second phase, transistors M₂, M₃ are turned on. With the capacitor banks the drive voltage at the gate of transistors M₁, M₂, M₃, M₄, are level-shifted by the direct-current (DC) voltage at Vcasc, increasing the driving strength of the transistors to reduce the R_{ON} of the transistors and increasing the OOB rejection of the filter. Using the capacitor bank 620, a level-shifted gate voltage (labeled “V_{g1,4}”) may be generated at the gate of transistors M₁, M₄, and using the capacitor bank 622, a level-shifted gate voltage (labeled “V_{g2,3}”) may be generated at the gate of transistors M₂, M₃, as described in more detail with respect to FIG. 7.

FIG. 7 is a timing diagram 700 illustrating level-shifted gate voltages and non-overlapping clock signals, in accordance with certain aspects of the present disclosure. As shown, when the clock signal φ₁ is logic low and the clock signal φ₂ is logic high during a first phase, transistors M₂, M₃ are turned on, sampling Vcasc on the capacitor bank 620. Thus, V_{g1,4} at the gate of transistors M₁, M₄ may be at Vcasc. Subsequently, during a second phase after the first phase, when the clock signal 1 transitions to logic high and the clock signal φ₂ transitions to logic low, the voltage on the capacitor bank 620 combines with the voltage (e.g., 0.8 volts) of the clock signal φ₁, generating the level-shifted gate voltage V_{g1,4} that is equal to 0.8 volts plus Vcasc, as shown.

In the same manner, the level-shifted gate voltage V_{g2,3} may be generated via the capacitor bank 622. That is, when the clock signal φ₂ is logic low and the clock signal φ₁ is logic high, transistors M₁, M₄ are turned on, sampling Vcasc on the capacitor bank 622. Thus, V_{g2,3} at the gate of transistors M₂, M₃ may be at Vcasc. Subsequently, when the clock signal φ₂ transitions to logic high and the clock signal φ₁ transitions to logic low, the voltage on the capacitor bank 622 combines with the voltage (e.g., 0.8 volts) of the clock signal φ₂, generating the level-shifted gate voltage V_{g2,3} that is equal to 0.8 volts plus Vcasc, as shown. By driving the transistors M₁, M₂, M₃, M₄ with level-shifted gate voltages, the R_{ON} of the transistors may be reduced, increasing the OOB rejection of the filter.

As shown, each of the capacitor banks 620, 622 may include a series of switches (e.g., switches 602-1 to 602-n and switches 606-1 to 606-n, n being any positive integer) to switch in or out respective capacitive elements and adjust a capacitance associated with the associated capacitor bank. The switches 602-1 to 602-n may be collectively referred to as “switches 602,” and the switches 606-1 to 606-n may be collectively referred to as “switches 606.” Using a digital bandwidth (BW) signal, one or more of the switches 602 may be closed to adjust the capacitance of the capacitor bank 620. Similarly, the BW signal may be used to close one or more of the switches 606 to adjust the capacitance of the capacitor bank 622. By adjusting the capacitance of the capacitor banks 620, 622, the bandwidth of the n-path filter may be adjusted. For example, the bandwidth may be adjusted to be narrower or wider depending on the capacitances of the capacitor banks 620, 622.

In effect, the n-path filter 600 implements two parallel filters. A first filter may be implemented via transistors M₁, M₂ and capacitive elements C_{S1-1} and C_{S1-2}, and a second filter may be implemented via transistors M₃, M₄ and capacitor banks 620, 622. The outer structure of the filter 600 including transistors M₁, M₂ and sampling capacitive elements C_{S1-1} and C_{S1-2} (e.g., fixed capacitive elements) provides a low total path resistance, resulting in higher OOB rejection. The low total path resistance may be due to transistors M₁, M₂ having a low R_{ON} since level-shifted gate voltages are used to drive transistors M₁ and M₂ and due to using fixed capacitive elements without switches that would otherwise increase R_{ON}.

The inner structure of the filter 600, including transistors M₃, M₄ and capacitor banks 620, 622, may be used to adjust the bandwidth of the n-path filter, as well as to generate the level-shifted gate voltages described herein. With the two sampling paths (e.g., inner structure and outer structure) being operated in parallel, the OOB rejection of the filter may be preserved (or increased) due to the total on-resistance of the filter being a function of the R_{ON} of transistor M₁ in parallel with the R_{ON} of the transistor M₄ as well as the R_{ON} of transistor M₂ in parallel with the R_{ON} of the transistor M₃. Alternatively, the capacitor banks 620, 622 may each be implemented using a fixed capacitive element (e.g., without switches to form a capacitor bank), providing a high OOB rejection and low insertion loss (e.g., albeit at a fixed bandwidth).

Referring back to FIG. 4, one or both of the filters 402, 404 may be implemented with an n-path filter such as the filter 600 described with respect to FIG. 6. With n-path filters, the LNA's OOB rejection may be reduced compared to using inductor-capacitor (LC) filters while providing bandwidth adjustability as described herein.

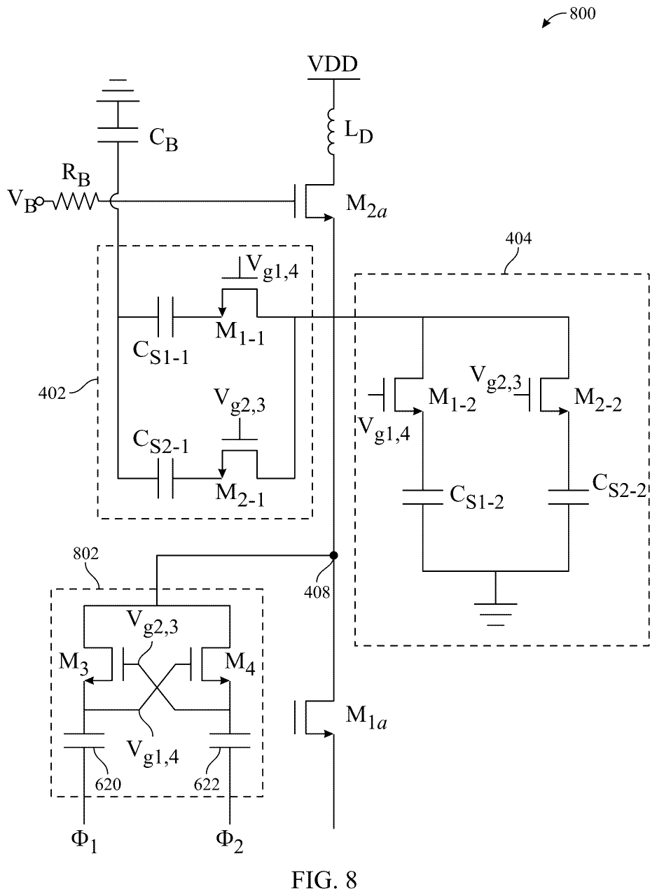

FIG. 8 illustrates an example LNA 800 implemented with a cross-coupled n-path filter 802 having a cross-coupled switch structure, in accordance with certain aspects of the present disclosure. The LNA 800 may correspond to LNA 400, with filters 402, 404 implemented with fixed-capacitor n-path filters. The LNA 800 also includes a cross-coupled n-path filter 802 to provide bandwidth adjustability while maintaining OOB rejection.

As shown, filter 402 may include an n-path filter implemented with transistors M₁₋₁, M₂₋₁ used to sample a voltage at node 408 on respective fixed capacitive elements C_{S1-1}, C_{S2-1}. Similarly, filter 404 may include an n-path filter implemented with transistors M₁₋₂, M₂₋₂ used to sample a voltage at node 408 on respective fixed capacitive elements C_{S1-2}, C_{S2-2}. Each of the filters 402, 404 may correspond to the inner structure of filter 600 including transistors M₁, M₂. A cross-coupled n-path filter 802 may be coupled to node 408, as shown. The cross-coupled n-path filter 802 may correspond to the inner structure of the filter 600 including transistors M₃, M₄ and capacitor banks 620, 622. As described, level-shifted gate voltages may be generated to drive the transistors M₃, M₄. As shown, the level-shifted gate voltage V_{g1,4} may be used to drive the gates of transistors M₁₋₁, M₁₋₂, M₄, and the level-shifted gate voltage V_{g2,3} may be used to drive the gates of transistors M₂₋₁, M₂₋₂, and M₃. The capacitance of each of the capacitor banks 620, 622 may be adjusted to adjust the bandwidth of the filtering performed at node 408.

In some implementations, an n-path filter may be coupled to a high impedance node of the LNA (e.g., the input or output of LNA), leading to increased filter rejection and lower insertion loss. However, coupling the n-path filter to a high impedance node may result in a narrow band filter response due to the large resistance-capacitance (RC) time constant resultant from the high-impedance node. Thus, the n-path filter may not be able to support filtering for the wide bandwidth of some technologies.

Certain aspects of the present disclosure are directed toward an n-path filter coupled to a low-impedance node providing a wide bandwidth response. The OOB rejection of the filter circuitry may be increased by using multiple filters, in some aspects. For example, filters 402, 404 may provide OOB rejection by shunting OOB signals to electric ground, as described herein. The filter 802 may provide additional rejection by shunting signal to electric ground. The generation of the level-shifted voltages as described herein lower the switch resistance (e.g., transistor on-resistance) of the n-path filter relative to the source impedance (e.g., impedance at cascode node 408). The insertion loss of the filters may be reduced by setting the gate-to-source voltage of the n-path filter transistors to be zero (e.g., relative to the voltage at the cascode node 408 which may be at VDD/2) when turned off.

The n-path filter described herein allows for tunable filtering with a wide bandwidth response. As described, one cross-coupled assisted n-path filter may be provided for bandwidth selection and level shifting of clock signals to drive two sets of fixed n-paths for filters 402, 404, providing bandwidth tuning while maintaining (or increasing) OOB jammer rejection (e.g., increasing adjacent channel filtering performance). Increasing adjacent channel filtering performance may also achieve current consumption and area reduction for the associated receiver chain including the LNA. In some cases, the switches of any n-path filter described herein may be opened (e.g., not controlled via a clock signal, but rather configured to remain open) to disable the n-path filter. While SAW/BAW filters work well for off-chip filtering, there is no equivalent on-chip filter that can operate across multiple protocols or multiple transceivers on the same chip. The filtering architecture provided herein allows for filtering of signals across different protocols/transceivers by providing a wideband filter response with a tunable bandwidth.

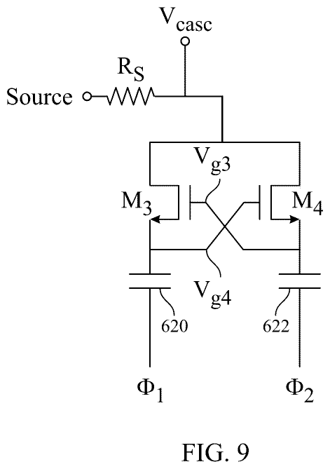

FIG. 9 illustrates an example n-path filter 900 implemented with a cross-coupled switch structure, in accordance with certain aspects of the present disclosure. As shown, the n-path filter 900 includes transistors M₃ and M₄ and capacitor banks 620, 622. As described with respect to FIG. 6, the transistors M₃ and M₄ and capacitor banks 620, 622 generate level shifted voltages such as voltages V_{g3} and V_{g4} (e.g., corresponding to voltages V_{g2,3} and V_{g1,4} shown in FIG. 6 and FIG. 8) driving the gates of transistors M₃ and M₄ respectively. As shown in diagram 700 of FIG. 7, the clock signal φ₁ may logic low or at zero volts (e.g., effectively electric ground) when transistor M₃ is turned on and the clock signal φ₂ may logic low or at zero volts (e.g., effectively electric ground) when transistor M₄ is turned on, providing a path to ground for the n-path filter 900. To generate the level shifted voltages, the clock signal φ₁ may transition to logic high or 0.8 volts when transistor M₃ is turned off and the clock signal φ₂ may transition to logic high or 0.8 volts when transistor M₄ is turned off (e.g., where the 0.8 volts combines with the voltage across the associated capacitor bank to generate a level shifted voltage). By driving the gates of transistors M₃ and M₄ using the level-shifted voltages, the driving strength for the transistors may be increased reducing on-resistance, as described herein.

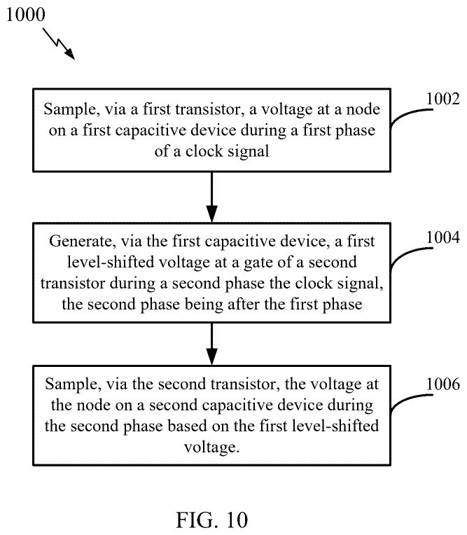

FIG. 10 is a flow diagram illustrating example operations 1000 for signal filtering, in accordance with certain aspects of the present disclosure. The operations 1000 may be performed, for example, by a filter circuit (e.g., filter 402, filter 404, or n-path filter 600) and/or an amplification circuit such as the LNA 400 or the LNA 800.

At block 1002, the filter circuit may sample, via a first transistor (e.g., transistor M₃ of FIG. 6), a voltage at a node (e.g., node 408 of FIG. 4) and on a first capacitive circuit (e.g., capacitor bank 620 of FIG. 6) during a first phase of a clock signal (e.g., clock signal φ₁). At block 1004, the filter circuit generates, via the first capacitive circuit, a first level-shifted voltage (e.g., V_{g1,4}) at a gate of a second transistor (e.g., transistor M₄) during a second phase of the clock signal (e.g., clock signal φ₂), the second phase being after the first phase. At block 1006, the filter circuit samples, via the second transistor, the voltage at the node and on a second capacitive circuit (e.g., capacitor bank 622) during the second phase based on the first level-shifted voltage.

In some aspects the filter circuit may also sample, via a third transistor (e.g., transistor M₁), the voltage at the node on a first capacitive element (e.g., C_{S1-1} of FIG. 6) during the first phase based on the first level-shifted voltage. The filter circuit may generate, via the second capacitive circuit, a second level-shifted voltage (e.g., V_{g2,3}) at a gate of the first transistor during a third phase of the clock signal, the third phase being after the first phase. The filter circuit may sample, via the first transistor, the voltage at the node on the first capacitive circuit during the third phase based on the second level-shifted voltage. In some aspects, the filter circuit may sample, via a fourth transistor (e.g., transistor M₂), the voltage at the node on a second capacitive element (e.g., C_{S1-2} of FIG. 6) during the third phase based on the second level-shifted voltage.

In some aspects, the filter circuit may adjust a capacitance associated with at least one of the first capacitive circuit or the second capacitive circuit to adjust a bandwidth associated with the signal filtering. For example, the first capacitive circuit may be a first capacitor bank, and the second capacitive circuit may be a second capacitor bank. The filter circuit may control a first set of switches (e.g., switches 602) of the first capacitor bank and a second set of switches (e.g., switches 606) of the second capacitor bank to adjust a bandwidth associated with the signal filtering.

In some aspects, the amplification circuit may generate an amplified signal via an amplifier. The amplifier may include: an input transistor (e.g., transistor Mia) with a gate coupled to an input voltage node (e.g., V_{I} node of FIG. 4). The amplifier may also include a cascode transistor (e.g., transistor M₂ₐ) with a source coupled to a drain of the input transistor, the node comprising a cascode node (e.g., node 408) between the source of the cascode transistor and the drain of the input transistor.

### Example Aspects

Aspect 1: An apparatus comprising a filter circuit, the filter circuit including: a first transistor including a first terminal coupled to a node; a second transistor including a first terminal coupled to the node; a first capacitive circuit coupled between a second terminal of the first transistor and a first clock node, the second terminal of the first transistor being further coupled to a gate of the second transistor; and a second capacitive circuit coupled between a second terminal of the second transistor and a second clock node, the second terminal of the second transistor being further coupled to a gate of the first transistor.
Aspect 2: The apparatus of Aspect 1, wherein: the first clock node is configured to receive a first clock signal; and the second clock node is configured to receive a second clock signal, the first clock signal being non-overlapping with the second clock signal.
Aspect 3: The apparatus of Aspect 1 or 2, wherein: the first capacitive circuit is configured to generate a first level-shifted voltage at the gate of the second transistor; and the second capacitive circuit is configured to generate a second level-shifted voltage at the gate of the first transistor.
Aspect 4: The apparatus according to any of Aspects 1-3, further comprising: a third transistor including a first terminal coupled to the node; a fourth transistor including a first terminal coupled to the node; a first capacitive element coupled between a second terminal of the third transistor and a reference potential node; and a second capacitive element coupled between a second terminal of the fourth transistor and the reference potential node.
Aspect 5: The apparatus of Aspect 4, wherein: the second terminal of the first transistor is further coupled to a gate of the fourth transistor; and the second terminal of the second transistor is further coupled to a gate of the third transistor.
Aspect 6: The apparatus according to any of Aspects 1-5, wherein: the first capacitive circuit comprises a first capacitor bank; and the second capacitive circuit comprises a second capacitor bank.
Aspect 7: The apparatus of Aspect 6, wherein: the first capacitor bank includes a first plurality of capacitive elements coupled in series with a first plurality of switches, respectively; and the second capacitor bank includes a second plurality of capacitive elements coupled in series with a second plurality of switches, respectively.
Aspect 8: The apparatus of Aspect 7, wherein the first plurality of switches and the second plurality of switches are configured to control a bandwidth associated with the filter circuit.
Aspect 9: The apparatus according to any of Aspects 1-8, further comprising an amplifier comprising the filter circuit, the amplifier comprising: an input transistor with a gate coupled to an input voltage node; and a cascode transistor with a source coupled to a drain of the input transistor, the node comprising a cascode node between the source of the cascode transistor and the drain of the input transistor.
Aspect 10: The amplifier of Aspect 9, wherein the filter circuit further comprises: a third transistor including a first terminal coupled to the node; a fourth transistor including a first terminal coupled to the node; a third capacitive element coupled between a second terminal of the third transistor and the gate of the cascode transistor; and a fourth capacitive element coupled between a second terminal of the fourth transistor and the gate of the cascode transistor.
Aspect 11: The apparatus according to any of Aspects 1-10, further comprising: an amplifier including: an input transistor with a gate coupled to an input voltage node; and a cascode transistor with a source coupled to a drain of the input transistor, the node comprising a cascode node between the source of the cascode transistor and the drain of the input transistor; and a first notch filter coupled between the node and a gate of the cascode transistor.
Aspect 12: The apparatus of Aspect 11, further comprising a second notch filter coupled between the node and a reference potential.
Aspect 13: The apparatus of Aspect 12, wherein the first notch filter comprises a first n-path filter, and wherein the second notch filter comprises a second n-path filter.
Aspect 14: A method for signal filtering, comprising: sampling, via a first transistor, a voltage at a node and on a first capacitive circuit during a first phase of a clock signal; generating, via the first capacitive circuit, a first level-shifted voltage at a gate of a second transistor during a second phase of the clock signal, the second phase being after the first phase; and sampling, via the second transistor, the voltage at the node and on a second capacitive circuit during the second phase based on the first level-shifted voltage.
Aspect 15: The method of Aspect 14, further comprising sampling, via a third transistor, the voltage at the node on a first capacitive element during the first phase based on the first level-shifted voltage.
Aspect 16: The method of Aspect 15, further comprising: generating, via the second capacitive circuit, a second level-shifted voltage at a gate of the first transistor during a third phase of the clock signal, the third phase being after the second phase; and sampling, via the first transistor, the voltage at the node on the first capacitive circuit during the third phase based on the second level-shifted voltage.
Aspect 17: The method of Aspect 16, further comprising sampling, via a fourth transistor, the voltage at the node on a second capacitive element during the third phase based on the second level-shifted voltage.
Aspect 18: The method according to any of Aspects 14-17, further comprising adjusting a capacitance associated with at least one of the first capacitive circuit or the second capacitive circuit to adjust a bandwidth associated with the signal filtering.
Aspect 19: The method according to any of Aspects 14-18, wherein: the first capacitive circuit comprises a first capacitor bank; the second capacitive circuit comprises a second capacitor bank; and the method further comprises controlling a first set of switches of the first capacitor bank and a second set of switches of the second capacitor bank to adjust a bandwidth associated with the signal filtering.
Aspect 20: The method according to any of Aspects 14-19, further comprising generating an amplified signal via an amplifier, the amplifier including: an input transistor with a gate coupled to an input voltage node; and a cascode transistor with a source coupled to a drain of the input transistor, the node comprising a cascode node between the source of the cascode transistor and the drain of the input transistor.
Aspect 21: An amplifier comprising: an input transistor with a gate coupled to an input voltage node; a cascode transistor with a source coupled to a drain of the input transistor; a first filter coupled between a source of the cascode transistor and a gate of the cascode transistor; and a load coupled between an output node of the amplifier and the cascode transistor.
Aspect 22: The amplifier of Aspect 21, wherein the first filter comprises a notch filter.
Aspect 23: The amplifier of Aspect 21 or 22, further comprising a second filter coupled between the source of the cascode transistor and a reference potential node.
Aspect 24: The amplifier of Aspect 23, wherein at least one of the first filter or the second filter includes: a first transistor including a first terminal coupled to the source of the cascode transistor; a second transistor including a first terminal coupled to the source of the cascode transistor; a first capacitive circuit coupled between a second terminal of the first transistor and a first clock node, the second terminal of the first transistor being further coupled to a gate of the second transistor; and a second capacitive circuit coupled between a second terminal of the second transistor and a second clock node, the second terminal of the second transistor being further coupled to a gate of the first transistor; a third transistor including a first terminal coupled to the source of the cascode transistor; a fourth transistor including a first terminal coupled to the source of the cascode transistor; a first capacitive element coupled between a second terminal of the third transistor and a reference potential node; and a second capacitive element coupled between a second terminal of the fourth transistor and the reference potential node.

### Additional Considerations

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another-even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. φ₁₁₂ (f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. An apparatus comprising a filter circuit, the filter circuit including:
a first transistor including a first terminal coupled to a node;
a second transistor including a first terminal coupled to the node;
a first capacitive circuit coupled between a second terminal of the first transistor and a first clock node, the second terminal of the first transistor being further coupled to a gate of the second transistor; and
a second capacitive circuit coupled between a second terminal of the second transistor and a second clock node, the second terminal of the second transistor being further coupled to a gate of the first transistor.

2. The apparatus of claim 1, wherein:
the first clock node is configured to receive a first clock signal; and
the second clock node is configured to receive a second clock signal, the first clock signal being non-overlapping with the second clock signal.

3. The apparatus of claim 1, wherein:
the first capacitive circuit is configured to generate a first level-shifted voltage at the gate of the second transistor; and
the second capacitive circuit is configured to generate a second level-shifted voltage at the gate of the first transistor.

4. The apparatus of claim 1, further comprising:
a third transistor including a first terminal coupled to the node;
a fourth transistor including a first terminal coupled to the node;
a first capacitive element coupled between a second terminal of the third transistor and a reference potential node; and
a second capacitive element coupled between a second terminal of the fourth transistor and the reference potential node.

5. The apparatus of claim 4, wherein:
the second terminal of the first transistor is further coupled to a gate of the fourth transistor; and
the second terminal of the second transistor is further coupled to a gate of the third transistor.

6. The apparatus of claim 1, wherein:
the first capacitive circuit comprises a first capacitor bank; and
the second capacitive circuit comprises a second capacitor bank.

7. The apparatus of claim 6, wherein:
the first capacitor bank includes a first plurality of capacitive elements coupled in series with a first plurality of switches, respectively; and
the second capacitor bank includes a second plurality of capacitive elements coupled in series with a second plurality of switches, respectively.

8. The apparatus of claim 7, wherein the first plurality of switches and the second plurality of switches are configured to control a bandwidth associated with the filter circuit.

9. The apparatus of claim 1, further comprising an amplifier comprising the filter circuit, the amplifier comprising:
an input transistor with a gate coupled to an input voltage node; and
a cascode transistor with a source coupled to a drain of the input transistor, the node comprising a cascode node between the source of the cascode transistor and the drain of the input transistor.

10. The amplifier of claim 9, wherein the filter circuit further comprises:
a third transistor including a first terminal coupled to the node;
a fourth transistor including a first terminal coupled to the node;
a third capacitive element coupled between a second terminal of the third transistor and the gate of the cascode transistor; and
a fourth capacitive element coupled between a second terminal of the fourth transistor and the gate of the cascode transistor.

11. The apparatus of claim 1, further comprising:
an amplifier including:
an input transistor with a gate coupled to an input voltage node; and
a cascode transistor with a source coupled to a drain of the input transistor, the node comprising a cascode node between the source of the cascode transistor and the drain of the input transistor; and
a first notch filter coupled between the node and a gate of the cascode transistor.

12. The apparatus of claim 11, further comprising a second notch filter coupled between the node and a reference potential.

13. The apparatus of claim 12, wherein the first notch filter comprises a first n-path filter, and wherein the second notch filter comprises a second n-path filter.

14. A method for signal filtering, comprising:
sampling, via a first transistor, a voltage at a node and on a first capacitive circuit during a first phase of a clock signal;
generating, via the first capacitive circuit, a first level-shifted voltage at a gate of a second transistor during a second phase of the clock signal, the second phase being after the first phase; and
sampling, via the second transistor, the voltage at the node and on a second capacitive circuit during the second phase based on the first level-shifted voltage.

15. The method of claim 14, further comprising sampling, via a third transistor, the voltage at the node on a first capacitive element during the first phase based on the first level-shifted voltage.

16. The method of claim 15, further comprising:
generating, via the second capacitive circuit, a second level-shifted voltage at a gate of the first transistor during a third phase of the clock signal, the third phase being after the second phase; and
sampling, via the first transistor, the voltage at the node on the first capacitive circuit during the third phase based on the second level-shifted voltage.

17. The method of claim 16, further comprising sampling, via a fourth transistor, the voltage at the node on a second capacitive element during the third phase based on the second level-shifted voltage.

18. An amplifier comprising:
an input transistor with a gate coupled to an input voltage node;
a cascode transistor with a source coupled to a drain of the input transistor;
a first filter coupled between a source of the cascode transistor and a gate of the cascode transistor; and
a load coupled between an output node of the amplifier and the cascode transistor.

19. The amplifier of claim 18, wherein the first filter comprises a notch filter.

20. The amplifier of claim 18, further comprising a second filter coupled between the source of the cascode transistor and a reference potential node.
